(19) United States
(12) Patent Application Publication
(10) Pub. No.: US 2008/0206965 A1
(43) Pub. Date: Aug. 28, 2008

(54) STRAINED SILICON MADE BY PRECIPITATING CARBON FROM Si(1-x-y)GexCy ALLOY

(75) Inventors: Oleg Gluschenkov, Poughkeepsie, NY (US); Yaocheng Liu, Elmsford, NY (US); Alexander Reznicek, Mount Kisco, NY (US); Devendra Sadana, Pleasantville, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/679,308

(22) Filed: Feb. 27, 2007

(51) Int. Cl. H01L 21/20

(52) U.S. Cl. 438/478

(57) ABSTRACT

Disclosed herein is a method of preparing strained silicon comprising annealing a carbon-doped silicon-germanium (SiGe:C) alloy containing region disposed adjacent to a silicon region, wherein the lattice constant of the SiGe:C alloy after annealing is greater than that of the SiGe:C alloy prior to annealing. The method can be used to prepare articles including metal oxide semiconductor field effect transistor (MOSFET) devices.

### BACKGROUND OF THE INVENTION

1. Field of the Invention

This invention relates to a method of making strained silicon, and particularly to a method of making strained silicon that involves forming carbon-doped SiGe alloy adjacent to a silicon region and precipitating the carbon from the carbon-doped SiGe alloy to provide a strained SiGe layer.

2. Description of Background

Strained silicon (Si) has been used to improve the performance of CMOS devices by improving the electron mobility through the silicon. Strained Si forms when a layer of silicon with a smaller atom spacing is grown on a substrate that has a larger lattice constant (i.e., greater spacing between atoms). The resulting silicon layer has a mismatched crystalline structure at the interface, which results in a distortion of the overlaying crystalline silicon or silicon alloy layer (i.e., the strained Si layer) to more closely match the adjacent lattice. The mismatch and resulting lattice strain provide improved semiconducting properties for the strained Si layer can allow electrons to flow at increased speeds, typically up to 70% faster or more depending on the amount of strain in the strained Si.

Different techniques have been developed to generate the strained-Si structures. Many of these techniques involve the epitaxial growth of silicon-germanium (SiGe) on Si or Si on SiGe, with a concentration gradient of Ge increasing from the substrate material to the epitaxial Si (strained) layer. In a typical process, strained Si is prepared by depositing of a graduated layer of silicon-germanium alloy on a silicon or silicon-on-insulator (SOI) substrate. On top of this, a “relaxed” layer of SiGe alloy is formed, and the stack is capped with an epitaxially grown (“strained”) layer of silicon. Ge is typically present in the SiGe layer in an amount of about b 20 to 30 mole percent based on the total number of moles of silicon and germanium. Generally, a higher mole fraction of Ge (i.e., greater than about 20 to 30 mole percent) in the SiGe layer leads to higher strain for the same structure. However, the higher Ge concentration can lead to lattice relaxation and defect generation, especially during the growth of the SiGe, and during the high thermal budget process afterwards.

For this reason, it is desirable to provide a strained Si layer that has the benefits of the higher molar amounts of Ge while avoiding the relaxation and defect formation in the SiGe layer and at the interface with the strained Si layer.

### SUMMARY OF THE INVENTION

The shortcomings of the prior art are overcome and additional advantages are provided through the provision of, in an embodiment, a method of preparing strained silicon comprising annealing a carbon-doped silicon-germanium (SiGe:C) alloy containing region disposed adjacent to a silicon region, wherein the lattice constant of the SiGe:C alloy after annealing is greater than that of the SiGe:C alloy prior to annealing. In an embodiment, the carbon doped SiGe alloy has empirical formula Si_{(1-x-y)}GeₓC_{y} wherein mole fractions x and y are each greater than 0, and x+y is less than 1. In another embodiment, the mole fraction x of Ge is 0.08 to 0.7 and mole fraction y of C is 0.008 to 0.07, based on the total mole fraction of Si, Ge, and C.

A method of forming a MOSFET device comprising strained silicon, comprises disposing a carbon-doped silicon-germanium (SiGe:C) alloy having an empirical formula Si_{(1-x-y)}GeₓC_{y} in a region adjacent to a silicon region, wherein mole fraction x of Ge is 0.08 to 0.7 and mole fraction y of C is 0.008 to 0.07 based on the total mole fraction of Si, Ge, and C, and the mole fraction x of Ge and mole fraction y of C are adjusted to x≧10y to evenly match the lattice constants of the alloy of empirical formula Si_{(1-x-y)}GeₓC_{y} and of Si, or to have a lattice constant mismatch with Si that is less than that obtained for an alloy of empirical formula Si_{(1-x-y)}GeₓC_{y} having the same value of x and a y value of 0, and wherein the SiGe:C alloy is disposed by epitaxial growth of the SiGe:C alloy, or the SiGe:C alloy is disposed by epitaxial growth of the SiGe alloy followed by carbon implant and subsequent thermal crystalline re-growth of the SiGe:C alloy by laser melting or flash anneal; and annealing the region containing the SiGe:C alloy at a temperature of about 500 to about 1,100° C., for a time of about 1 second to about 60 hours, wherein during annealing the carbon (C) in the SiGe:C alloy migrates from substitutional lattice sites in the SiGe:C alloy to interstitial spaces sites, wherein the relative number of moles of C present in the substitutional lattice sites is less than or equal to about 0.5% based on the total moles of Si, Ge, and C, and wherein the lattice constant of the SiGe:C alloy after annealing is greater than that of the SiGe:C alloy prior to annealing.

In another embodiment, an article prepared according to the above method is a metal oxide semiconductor field effect transistor (MOSFET) device.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically we have achieved a solution which provides strained carbon doped silicon-germanium (SiGe:C), prepared from an unstrained or minimally strained carbon doped silicon-germanium, with the result that the strained SiGe:C has lower defect levels at the interface with an adjacent strained silicon region than would be obtained using a SiGe region having a comparable Ge loading. The method is particularly useful where high amounts (up to 70 mole percent) of Ge are used in the SiGe:C, based on the total number of moles of Si, Ge, and C.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates one example of a method for making a strained silicon layer in a metal oxide semiconductor field effect transistor (MOSFET) according to an embodiment.

The detailed description explains the preferred embodiments of the invention, together with advantages and features, by way of example with reference to the drawings.

### DETAILED DESCRIPTION OF THE INVENTION

As disclosed herein, a device having strained silicon can be prepared by forming an unstrained carbon-doped silicon-germanium alloy (SiGe:C) region disposed adjacent to an epitaxial silicon region having a comparable lattice constant, and annealing to precipitate carbon from the substitutional lattice sites within the SiGe:C region. As used herein, “disposed adjacent to” means in at least partial contact with. The resulting annealed SiGe:C region has a higher lattice constant than the adjacent Si region (where the magnitude of the lattice constants follows the trend Si<SiGe:C<SiGe), thereby creating strain in the Si region and thereby forming strained Si. In this way, SiGe:C alloy regions containing higher levels of Ge of up to 70 mole percent (a mole fraction of 0.7) based on the molar content of Si, Ge and C can be made with low interfacial defect levels, and made to avoid relaxation of the lattice constant with the increasing amounts of Ge.

In the method, a carbon doped silicon-germanium alloy is initially deposited adjacent to a silicon region where the SiGe:C alloy is approximately lattice matched to the silicon, or has a reduced lattice mismatch relative to the silicon when compared to the lattice constant of SiGe that is not doped with C, and subsequently annealed to precipitate carbon from the substitutional lattice sites within the crystalline structure of the SiGe:C to the interstitial spaces. Deposition of the SiGe:C alloy may be done using a known method. In an embodiment, SiGe:C alloy of the desired proportion may be epitaxially grown onto a substrate by chemical vapor deposition (CVD). In another embodiment, SiGe is initially deposited by CVD in the desired proportion, followed by implant of carbon into the SiGe alloy by an implant method. Implanting C into the SiGe region may in this way be used to achieve the desired C concentration, followed by subsequent use of a thermal crystal re-growth technique such as, for example, laser melting (anneal) or flash anneal to heat up the substrate and melt the C doped SiGe alloy, which has a lower melting point than Si. Upon cooling, the SiGe:C alloy re-grows with a lattice constant close to that of Si. The C precipitation step can be a subsequent anneal after the re-growth of the SiGe:C alloy, or the C precipitation may be incorporated into an existing subsequent thermal step in the CMOS process.

In the same lattice, Ge and C can be proportioned to counterbalance the opposing effects of the higher lattice constant for Ge and the smaller lattice constant for C to adjust the net lattice constant to that of Si. In an embodiment, the SiGe:C alloy has an empirical formula of Si_{(1-x-y)}GeₓC_{y} where mole fractions x and y are each greater than 0 and x+y is less than 1, and the concentrations (i.e., mole fractions) of Ge and C can provide a lattice constant for the SiGe:C alloy that can evenly match that of Si when x is equal to about 10y, though an exact match of the lattice constants is not necessary. In instances where y<0.1x, the lattice constant of SiGe:C is still smaller than that of SiGe and therefore the lattice mismatch with Si is sufficiently reduced so as to minimize the level of mismatch defects. For example, in the above empirical formula, a carbon mole fraction y of about 0.02 is sufficient to reduce the lattice constant of an SiGe:C alloy with a germanium mole fraction x of about 0.5 to that of a SiGe alloy having a Ge mole fraction of about 0.3 and an Si mole fraction of about 0.7. Thus, in an embodiment, x≧10y for an alloy having the empirical formula Si_{(1-x-y)}GeₓC_{y}. In another embodiment, the mole fraction x of Ge and mole fraction y of C are adjusted to x≧10y to evenly match the lattice constants of the alloy of empirical formula Si_{(1-x-y)}GeₓC_{y} and of Si, or to have a lattice constant mismatch with Si that is less than that obtained for an alloy of empirical formula Si_{(1-x-y)}GeₓC_{y} having the same value of x and a y value of 0.

In an embodiment, the relative mole fraction x of Ge is 0.08 to 0.7, specifically 0.1 to 0.6, and more specifically 0.1 to 0.5 based on the total mole fraction of Si, Ge, and C. In a specific embodiment, the relative mole fraction x of Ge is 0.3 to 0.5 based on the total mole fraction of Si, Ge, and C. In another embodiment, the relative mole fraction y of C is 0.008 to 0.07, specifically 0.01 to 0.05, and more specifically 0.01 to 0.02, based on the total mole fraction of Si, Ge, and C.

Due to the small or zero lattice mismatch, misfit defects between the adjacent SiGe:C alloy and Si are minimized or absent during the epitaxial growth of the SiGe:C alloy. After the alloy is in place, a low-temperature anneal can be used to precipitate C atoms from the substitutional lattice sites to the interstitial spaces. The anneal may be accomplished using a known method, such as by annealing in an annealing furnace, by rapid thermal processing (RTP), or other suitable technique. In an embodiment, annealing is carried out at a temperature of about 500 to about 1,100° C., specifically about 600 to about 1,000° C. The time for the annealing step can be from about 1 second to about 60 hours, and is dependent upon the temperature, used in the annealing process. In an embodiment, where the anneal temperature is about 600° C., the anneal time is about 30 minutes to about 60 hours. In another embodiment, where the anneal temperature is about 800° C., the anneal time is about 1 second to about 5 minutes. In another embodiment, where the anneal temperature is about 1,000° C. to about 1,100° C., the anneal time is less than or equal to about 1 second. Annealing may be performed under inert atmosphere, i.e., nitrogen or argon, or where appropriate, under reducing atmosphere such as forming gas (H₂/N₂ atmosphere). Annealing may be done at any time after the deposition of the SiGe:C alloy during the fabrication of the CMOS structures (i.e., the “front end of line” processes), and prior to the fabrication of the interconnects (i.e., “back end of line” processes). The annealing step can be readily implemented since C is thermodynamically unstable at the substitutional lattice sites, and therefore the migration of the C out from the substitutional lattice sites, also referred to herein as “C precipitation”, is energetically favored. In an embodiment, the relative number of moles of C present in the substitutional lattice sites is less than or equal to 0.5% based on the total moles of Si, Ge, and C. In another embodiment, the relative number of moles of C present in the substitutional lattice sites is 0% based on the total moles of Si, Ge, and C. As a result of the C precipitation, the lattice constant of the Si_{(1-x-y)}GeₓC_{y} alloy increases, leading to the strain increase in the designated adjacent Si regions. Because this anneal is a relatively low-temperature process, the chance of forming misfit (i.e., lattice mismatch) dislocations and relaxing the strain is minimized.

In this way, the carbon can be relocated in the crystal lattice to allow for a high lattice constant in the SiGe:C alloy, wherein the net composition for a region which includes the SiGe:C alloy, such as a layer, filled trench, or the like, is constant based on the initial composition of the SiGe:C alloy. Precipitation of the carbon from the SiGe:C lattice causes the SiGe lattice to contract and form a strained SiGe layer. It is thus possible to incorporate high Ge concentration in a SiGe:C alloy to achieve highly strained Si in an adjacent region.

CMOS devices can be prepared using the above method by following the traditional epi-SiGe process in which a transistor gate stack and spacer are formed, followed by recessed Si etch adjacent to the gate stack to form a trench, and selective SiGe growth with high Ge fraction. Some misfit defects may be generated in the SiGe alloy due to the high Ge fraction; however, the use of the above method can minimize the formation of such effects. An exemplary process using the above method is described below.

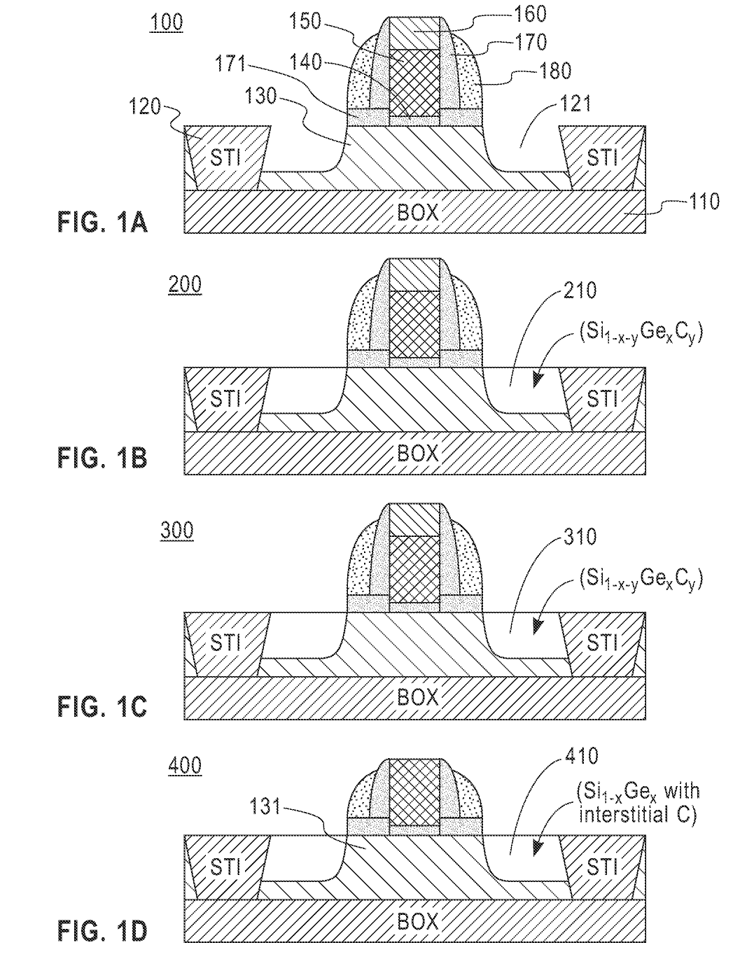

Referring now to the drawings, FIG. 1 shows an exemplary embodiment of a MOSFET device 400 prepared using a silicon-on-insulator (SOI) substrate structure. In FIG. 1, structure 100 includes a buried silicon dioxide (BOX) substrate 110 which has shallow trench isolation (STI) 120 and epitaxial silicon in a channel 130, all disposed on a surface of BOX substrate 110. In another embodiment, a substrate other than BOX, such as silicon, SiGe, Si₃N₄, or other substrate, can be used. On a surface of the channel 130 opposite BOX substrate 110, a gate oxide 140 and spacer 171 is disposed, with gate 150 disposed on a surface of the gate oxide 140 opposite the channel 130. Also in structure 100, a cap layer 160 is disposed on a surface of the gate 150 opposite gate oxide 140, a first spacer 170 is disposed on a side surface of the gate 150 and top surface of the spacer 171, and a second spacer 180 is disposed on a side surface of first spacer 170 opposite the gate 150. A shallow trench 121 is located between the STI 120 and the channel 130.

The shallow trench 121 (from structure 100) is, in structure 200, selectively filled with SiGe:C layer 210 having an empirical formula of Si_{(1-x-y)}GeₓC_{y}. These shallow trenches, when filled, form the source and drain (not shown) of the transistor structure depicted in FIG. 1, and are interchangeable as depicted. In an embodiment, the SiGe:C layer 210 is epitaxially (also referred to as “epi”) grown SiGe:C alloy of the desired stoichiometry. In another embodiment, the SiGe:C layer 210 is formed in a two-step method by first epitaxially growing SiGe alloy, and subsequently implanting carbon to form an Si_{(1-x-y)}GeₓC_{y} alloy of the desired stoichiometry. Where the SiGe:C layer 210 is formed by the two-step method, the SiGe with implanted C is then thermally treated by, in an embodiment, laser melting followed by re-growth of the crystalline SiGe:C layer 310 in structure 300. Where the Si_{(1-x-y)}GeₓC_{y} alloy is directly epitaxially grown, laser melting and re-growth is unnecessary and the SiGe:C layer 310 in structure 300 is obtained directly.

Structure 300 is then annealed at a temperature of 500 to 1,100° C. to form the desired stressor layer 410 shown in MOSFET structure 400. The role of the stressor layer, which has a higher lattice constant than the unannealed layer 310, is to transfer the stress by inducing the adjacent channel 130 with its lower lattice constant to more closely match the higher lattice constant of the annealed stressor layer 410, to provide a stressed channel 131. Stressed channel 131 thereby can provide a MOSFET device 400 with improved performance, and lower defectivity in the stressor layer 410 and the stressed channel 131.

As one example, one or more aspects of the present invention can be included in an article of manufacture (e.g., one or more semiconductor devices incorporating an embodiment of the foregoing MOSFET structure), where the articles are useful in the manufacture of semiconductor microchips. In a specific embodiment, an article comprises a MOSFET structure prepared according to the method disclosed herein. The article of manufacture can be included as a part of an electronic device or sold separately.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

All publications, patents and patent applications cited in this specification are herein incorporated by reference, and for any and all purposed, as if each individual publication, patent or patent application were specifically and individually indicates to be incorporated by reference. In the case of inconsistencies, the present disclosure will prevail.

The term “comprising” (and its grammatical variations) as used herein is used in the inclusive sense of “having” or “including” and not in the exclusive sense of “consisting only of”. The singular forms “a,” “an,” and “the” include plural referents unless the context clearly dictates otherwise. The endpoints of all ranges reciting the same characteristic or component are independently combinable and inclusive of the recited endpoint. All references are incorporated herein by reference. The terms “first,” “second,” and the like herein do not denote any order, quantity, or importance, but rather are used to distinguish one element from another. As used herein and unless otherwise specified, a feature that “forms on”, “is formed on”, and “is forming on” another feature, or “disposed on” or “disposed adjacent to” another feature, mean that the feature so formed or disposed is in at least partial contact with the other feature.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method of preparing strained silicon comprising:
annealing a carbon-doped silicon-germanium (SiGe:C) alloy-containing region disposed adjacent to a silicon region,
wherein the lattice constant of the SiGe:C alloy after annealing is greater than that of the SiGe:C alloy prior to annealing.

2. The method of claim 1, wherein the carbon doped SiGe alloy has empirical formula Si_{(1-x-y)}GeₓC_{y} wherein mole fractions x and y are each greater than 0, and x+y is less than 1.

3. The method of claim 2, wherein the mole fraction x of Ge is 0.08 to 0.7 and mole fraction y of C is 0.008 to 0.07, based on the total mole fraction of Si, Ge, and C.

4. The method of claim 2, wherein the mole fraction x of Ge and mole fraction y of C are adjusted to evenly match the lattice constants of an alloy of empirical formula Si_{(1-x-y)}GeₓC_{y} and of Si, or to have a lattice constant mismatch with Si that is less than that obtained for an alloy of empirical formula Si_{(1-x-y)}GeₓC_{y} having the same value of x and a y value of 0.

5. The method of claim 2, wherein x≧10y.

6. The method of claim 1, wherein the SiGe:C alloy is disposed by epitaxial growth of the SiGe:C alloy.

7. The method of claim 1, wherein the SiGe:C alloy is disposed by epitaxial growth of the SiGe alloy followed by carbon implant, and subsequent thermal crystalline re-growth of the SiGe:C alloy.

8. The method of claim 7, wherein the thermal re-growth of the SiGe:C alloy is done using laser melting or flash anneal.

9. The method of claim 1, wherein the annealing is carried out at a temperature of about 500 to about 1,100° C., for a time of about 1 second to about 60 hours.

10. The method of claim 1, wherein the carbon (C) in the SiGe:C alloy migrates out from substitutional lattice sites in the SiGe:C alloy, and wherein the relative number of moles of C present in the substitutional lattice sites is less than or equal to 0.5% based on the total moles of Si, Ge, and C.

11. An article prepared by the method of claim 1.

12. The article of claim 11, wherein the article is a metal oxide semiconductor field effect transistor (MOSFET) device.

13. A method of forming a MOSFET device comprising strained silicon, comprising:
disposing a carbon-doped silicon-germanium (SiGe:C) alloy having an empirical formula Si_{(1-x-y)}GeₓC_{y} in a region adjacent to a silicon region, wherein mole fraction x of Ge is 0.08 to 0.7 and mole fraction y of C is 0.008 to 0.07 based on the total mole fraction of Si, Ge, and C, and the mole fraction x of Ge and mole fraction y of C are adjusted to x≧10y to evenly match the lattice constants of the alloy of empirical formula Si_{(1-x-y)}GeₓC_{y} and of Si, or to have a lattice constant mismatch with Si that is less than that obtained for an alloy of empirical formula Si_{(1-x-y)}GeₓC_{y} having the same value of x and a y value of 0, and
wherein the SiGe:C alloy is disposed by epitaxial growth of the SiGe:C alloy, or the SiGe:C alloy is disposed by epitaxial growth of the SiGe alloy followed by carbon implant and subsequent thermal crystalline re-growth of the SiGe:C alloy by laser melting or flash anneal; and
annealing the region containing the SiGe:C alloy at a temperature of about 500 to about 1,100° C., for a time of about 1 second to about 60 hours,
wherein during annealing the carbon (C) in the SiGe:C alloy migrates from substitutional lattice sites in the SiGe:C alloy to interstitial spaces sites, wherein the relative number of moles of C present in the substitutional lattice sites is less than or equal to about 0.5% based on the total moles of Si, Ge, and C, and
wherein the lattice constant of the SiGe:C alloy after annealing is greater than that of the SiGe:C alloy prior to annealing.
